(19) United States
(12) Patent Application Publication
(10) Pub. No.: US 2023/0046162 A1
(43) Pub. Date: Feb. 16, 2023

(54) POUCH-SHAPED BATTERY HAVING SWELLING SENSING UNIT ADDED THERETO

(71) Applicant: LG Energy Solution, LTD., Seoul (KR)

(72) Inventor: Hyeon Jin Song, Daejeon (KR)

(21) Appl. No.: 17/792,119

(22) PCT Filed: Feb. 8, 2021
(86) PCT No.: PCT/KR2021/001666

§ 371 Date: Jul. 11, 2022

(30) Foreign Application Priority Data
Mar. 9, 2020 (KR) 10-2020-0028924

(51) Int. Cl. H01M 10/48; H01M 50/211; H01M 10/613; H01M 10/647; H01M 50/105

(52) U.S. Cl. CPC H01M 10/482; H01M 50/211; H01M 10/613; H01M 10/647; H01M 50/105

(57) ABSTRACT

A battery including a swelling sensing unit. The battery includes a case and an electrode assembly in the case. The battery further includes a film on a surface of the battery. The film includes a predetermined amount of elasticity or having substantially no elasticity.

### CROSS-REFERENCE TO RELATED APPLICATIONS

This application is a National Phase entry pursuant to 35 U.S.C. § 371 of International Application No. PCT/KR2021/001666 filed on Feb. 8, 2021, and claims priority to and the benefit of Korean Patent Application No. 10-2020-0028924 filed on Mar. 9, 2020 with the Korean Intellectual Property Office, the disclosure of which is incorporated herein by reference in its entirety.

### TECHNICAL FIELD

The present disclosure relates to a pouch-shaped battery having a swelling sensing unit added thereto. One particular implementation of the present disclosure relates to a pouch-shaped battery having a swelling sensing unit added thereto, wherein the swelling sensing unit is configured to easily sense swelling of the pouch-shaped battery due to overcharging, etc.

### BACKGROUND

Details in the background section do not constitute the related art but are given only as background information concerning the subject matter of the present disclosure.

A lithium secondary battery is mainly classified as a cylindrical battery, a prismatic battery, or a pouch-shaped battery based on the external shape thereof, and is also classified as a lithium ion battery, a lithium ion polymer battery, a lithium polymer battery, or an all-solid-state battery based on the type of an electrolytic solution.

With miniaturization of mobile devices, demand for a pouch-shaped battery, which is easily deformed, is manufactured at low cost, and is lightweight, is high.

FIG. 1 is an exploded perspective view of a related pouch-shaped battery. Referring to FIG. 1, the pouch-shaped battery 10 includes an electrode assembly 30, electrode tabs 40 and 50 extending from the electrode assembly 30, electrode leads 60 and 70 welded respectively to the electrode tabs 40 and 50, and a battery case 20 configured to receive the electrode assembly 30.

The electrode assembly 30 is a power-generating element configured such that a positive electrode and a negative electrode are sequentially stacked in the state in which a separator is interposed therebetween, and is configured to have a stacked type structure or a stacked/folded type structure. The electrode tabs 40 and 50 extend from respective electrode plates of the electrode assembly 30, and the electrode leads 60 and 70 are electrically connected respectively to the plurality of electrode tabs 40 and 50 extending from the respective electrode plates, for example, by welding, wherein a portion of each electrode lead is exposed outwards from the battery case 20. An insulative film 80 is attached to a portion of each of the upper and lower surfaces of each of the electrode leads 60 and 70 in order to improve the seal with the battery case 20 and at the same time to guarantee an electrically insulated state. The battery case 20 is made of an aluminum laminate sheet, provides a space capable of receiving the electrode assembly 30, and is generally formed so as to have a pouch shape.

The related pouch-shaped battery is not provided with a simple sensing unit configured to measure swelling of the battery due to overcharging, etc. In order to sense swelling of a battery, a strain gauge or a piezoelectric pressure sensor may be attached to the surface of the battery so as to sense a change in shape of the battery.

However, such a method has difficulty sensing overall swelling of the battery and is of no practical use. It is possible to sense only a change in shape of a specific region using the above method, and a plurality of sensors must be attached over a wide range of the battery in order to sense overall swelling of the battery. In the case in which the plurality of sensors is attached, a plurality of electrical lines, such as power lines configured to supply power to the sensors and sensing lines extending from the sensors, must also be connected. Recent batteries requiring high capacities have no spatial margins necessary to dispose such additional parts.

In many cases, the pouch-shaped battery is used as a part of a battery pack, although the pouch-shaped battery is also individually used. In this case, sensing swelling of the pouch-shaped battery may be important information necessary to determine whether the pouch-shaped battery is abnormal when considering a safety-related problem of the pouch-shaped battery (cell) disposed in the battery pack.

Therefore, it is necessary to introduce technology capable of sensing overall swelling of the pouch-shaped battery in order to macroscopically determine whether the battery (cell) is abnormal.

Also, in the case in which pouch-shaped batteries are stacked in the battery pack, it is necessary to efficiently transfer heat generated therein to the outside in order to cool the battery pack. However, technology capable of efficiently disposing a simple structure, configured to transfer such heat to the outside, in the battery pack has not been definitely suggested.

In Patent Document 1, the surface of a thin film configured to wrap a battery 8 is used as a reflective region, a light source 4 configured to emit light is provided at the inner surface of a detection cover configured to wrap the battery, reflected light is detected by a light detection region 5 formed in the inner surface of a detection cover in order to determine whether the battery swells. When the battery swells, light emitted by the light source 4 and reflected by the surface of the battery is changed, whereby the light detection region 5 senses such change. Patent Document 1 has a problem in that the reflective region is provided over the entire surface of the battery, whereby sensors must be widely disposed. Patent Document 1 is meaningful in the case in which it is necessary to sense the overall form in which the battery swells. However, a device for sensing swelling of the battery is too complicated and thus a wide space is needed to receive the device. Consequently, Patent Document 1 is not suitable for existing high-capacity batteries.

In Patent Document 2, optical fibers configured to reflect light are provided at the outer surface of a battery, light is irradiated through the optical fibers in order to measure the pressure of each battery module in a battery pack. In Patent Document 2, a method of measuring change in pressure using light is performed by a device in which a plurality of diffraction slits is disposed so as to be spaced apart from each other by a predetermined distance, when physical deformation occurs due to a change in pressure, the distance between the diffraction slits is changed, whereby a change in wavelength of light passing through the slits is measured to sense pressure.

Patent Document 3 discloses a swelling sensing method in the case in which a conductor configured to wrap an electrode assembly is cut by swelling. However, a separate current measurement device must be provided in a battery, safety of the battery may be adversely affected by the conductor, and there is a spatial limitation in providing a battery supply device and a detection device.

Patent Document 4 discloses technology for preventing swelling of a battery using a material configured to shrink when the temperature of the material increases.

Technology capable of sensing overall swelling of a pouch-shaped battery in order to macroscopically determine whether the battery (cell) is abnormal while overcoming such a spatial limitation and technology capable of efficiently disposing a simple structure, configured to efficiently transfer heat generated in pouch-shaped batteries to the outside in order to cool the pouch-shaped batteries in the case in which the pouch-shaped batteries are stacked in a battery pack, in a space defined in the battery pack have not yet been definitely suggested.

### Prior Art Documents

(Patent Document 1) Chinese Utility Model Publication No. 208013385 (2018 Oct. 26)

(Patent Document 2) Japanese Patent Application Publication No. 2009-059582 (2009 Mar. 2019)

(Patent Document 3) Korean Patent Application Publication No. 2011-0037378 (2011 Apr. 13)

(Patent Document 4) Korean Patent Application Publication No. 2014-0050182 (2014 Apr. 29)

### SUMMARY

The present disclosure has been made in view of the above problems, and embodiments of the present disclosure are to provide 1) technology capable of sensing overall swelling of a pouch-shaped battery in order to macroscopically determine whether the battery (cell) is abnormal while overcoming such a spatial limitation and 2) technology capable of efficiently disposing a simple structure, configured to efficiently transfer heat generated in pouch-shaped batteries to the outside in order to cool the pouch-shaped batteries in the case in which the pouch-shaped batteries are stacked in a battery pack, in a space defined in the battery pack.

According to one embodiment of the present disclosure, provides a pouch-shaped battery having a lead protruding from at least one side surface thereof, wherein a reflective film is added to the one side surface, from which the lead protrudes. The reflective film may be a visible light reflective film.

A heat shrinkable film may be added so as to wrap the surface of the pouch-shaped battery, and a conductive film may be further added between the heat shrinkable film and the pouch-shaped battery. The conductive film has at least one protrusion formed on the one side surface, from which the lead protrudes. Meanwhile, the heat shrinkable film or the conductive film and the reflective film may be integrated.

In order to sense swelling of the pouch-shaped battery, it is preferable for the reflective film to lack elasticity. In the case in which the pouch-shaped battery swells, the inelastic reflective film must be torn or cut. It is preferable that the reflective film be made of a material that has no danger of fire even in the case in which the temperature of a battery cell is high while being capable of being easily damaged by tensile strength, such as film or paper.

A battery pack including at least one pouch-shaped battery according to the present invention has a swelling sensing unit added thereto, wherein the swelling sensing unit includes a light irradiation portion and a sensor configured to sense tear or cutting of the reflective film.

The battery pack may further include at least one cooling portion disposed in contact with the protrusion.

A method of sensing swelling of the pouch-shaped battery in the battery pack according to the present invention includes:

a) a step of the light irradiation portion irradiating the reflective film of a target pouch-shaped battery with light;

b) a step of the sensor sensing light reflected by the reflective film; and

c) a step of determining that the target pouch-shaped battery has swelled in a case in which the sensor does not sense light reflected by the reflective film.

When the pouch-shaped battery expands due to swelling, whereby the reflective film is torn, and therefore light reflected by the reflective film is not sensed, the pouch-shaped battery may be determined to have swelled.

The pouch-shaped battery may be disposed in the battery pack, and the light irradiation portion and the sensor may be disposed at a side surface of the battery pack.

The method may further include a step of wrapping the surface of the pouch-shaped battery with the conductive film, adding the reflective film to the one side surface, from which the lead protrudes, and wrapping the surface of the pouch-shaped battery with the heat shrinkable film before the pouch-shaped battery is disposed in the battery pack.

According to an embodiment of the present disclosure, a battery comprises: a case; an electrode assembly in the case; and a film on a surface of the battery, the film having a predetermined amount of elasticity or having substantially no elasticity. The film is a visible light reflective film. The battery comprises a heat shrinkable film on the case.

The battery further comprises a heat conductive film between the heat shrinkable film and the case. The heat conductive film comprises a protrusion formed on the surface. The heat shrinkable film or the conductive film is integrated with the film.

According to one embodiment of the present disclosure, a battery pack comprises the battery disclosed above, and further comprises: a swelling sensing unit, the swelling sensing unit comprising a light irradiation portion and a sensor. The sensor senses light reflected from the film.

The battery pack further comprises a cooling portion coupled to a protrusion formed on the surface.

According to one embodiment of the present disclosure, a method of sensing swelling of the battery in the battery pack disclosed above is provided. The method comprises: irradiating, by the light irradiation portion, the film of the battery with light; sensing, by the sensor, the light reflected from the film; and determining, by the swelling sensing unit, swelling of the battery based on an amount of light sensed by the sensor. The method further comprises determining that the battery is swelled when the swelling sensing unit determines the amount of light sensed by the sensor has changed.

In one embodiment, the battery is in the battery pack, and the light irradiation portion and the sensor are at a side of the battery pack. In one embodiment, the film is made of paper. In one embodiment, the film is cut or torn when a predetermined amount of tensile strength is applied to the film. The protrusion conducts heat from the heat conductive film. A part of the heat shrinkable film or a part of the heat conductive film is the film. The film comprises a partial incision portion.

According to an embodiment of the present disclosure, a battery pack comprises: a plurality of batteries, each of the plurality of batteries comprising a film on a surface of each of the plurality of batteries; and a swelling sensing unit, the swelling sensing unit comprising a light irradiation portion and a sensor. At least one of the plurality of batteries is a target battery. The light irradiation portion irradiates light on the film of the target battery. The sensor senses light reflected from the film of the target battery. The swelling sensing unit determines swelling of the battery based on an amount of light sensed by the sensor.

According to an embodiment of the present disclosure, a method of sensing swelling of a target battery of a battery pack is provided. The battery pack comprises: a plurality of batteries, each of the plurality of batteries comprising a film on a surface of each of the plurality of batteries; and a swelling sensing unit, the swelling sensing unit comprising a light irradiation portion and a sensor. At least one of the plurality of batteries is a target battery. The method comprises: irradiating, by the light irradiation portion, a film of the target battery with light; sensing, by the sensor, the light reflected from the film; and determining, by the swelling sensing unit, swelling of the battery based on an amount of light sensed by the sensor.

The present invention may be provided in the state in which an arbitrary combination of the invention is possible.

### DESCRIPTION OF DRAWINGS

The accompanying drawings constitute a part of the specification, illustrate one or more embodiments in the disclosure, and together with the specification, explain the disclosure.

FIG. 1 is an exploded perspective view showing a general structure of a related pouch-shaped battery.

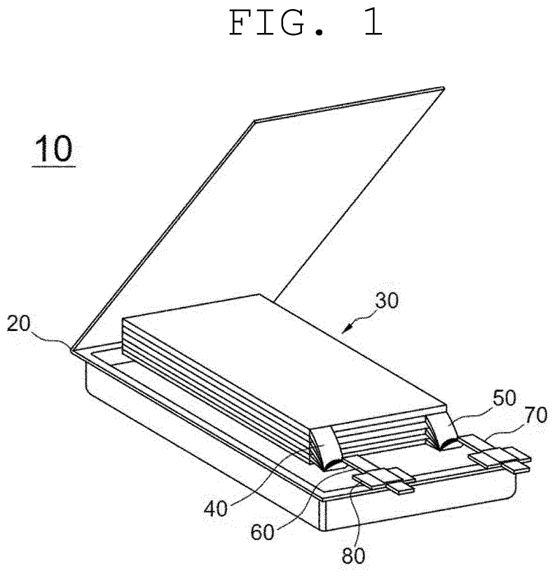

FIG. 2 is a perspective view of a pouch-shaped battery according to an embodiment of the present disclosure.

FIG. 3 is a side sectional view of the pouch-shaped battery according to the embodiment of the present disclosure.

FIG. 4 is a perspective view of a battery pack according to an embodiment of the present disclosure.

FIG. 5 is an AA′ sectional view of the battery pack according to the embodiment of the present disclosure.

FIG. 6 is a schematic view showing a swelling sensing method according to an embodiment of the present disclosure.

### DETAILED DESCRIPTION

### Best Mode

Now, preferred embodiments of the present disclosure will be described in detail with reference to the accompanying drawings such that the preferred embodiments of the present disclosure can be easily implemented by a person having ordinary skill in the art to which the present disclosure pertains. In describing the principle of operation of the preferred embodiments of the present disclosure in detail, however, a detailed description of known functions and configurations incorporated herein will be omitted when the same may obscure the subject matter of the present disclosure.

In addition, the same reference numbers will be used throughout the drawings to refer to parts that perform similar functions or operations. In the case in which one part is said to be connected to another part in the specification, not only may the one part be directly connected to the other part, but also, the one part may be indirectly connected to the other part via a further part. In addition, that a certain element is included does not mean that other elements are excluded, but means that such elements may be further included unless mentioned otherwise.

Hereinafter, a preferred manufacturing example and embodiments will be presented together with the drawings in order to assist in understanding the present disclosure. These are provided in order to illustrate the present disclosure and do not limit the scope of the present disclosure.

Here, the present disclosure will be described in more detail.

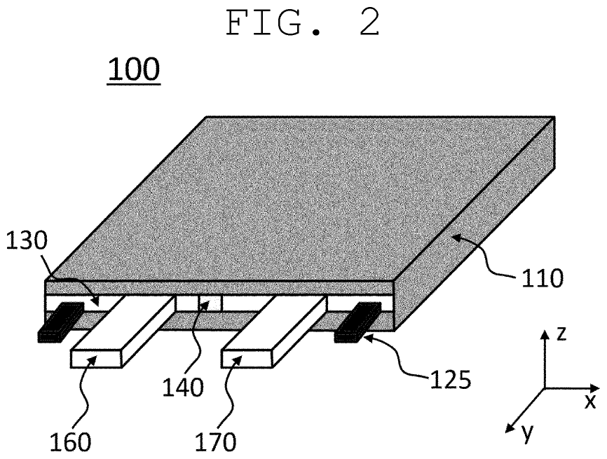

FIG. 2 is a perspective view of a pouch-shaped battery 100 according to an embodiment of the present disclosure.

Positive and negative electrode leads 160 and 170 protrude from one side surface of the pouch-shaped battery 100. A reflective film 140 is added to the one side surface of the pouch-shaped battery 100. The reflective film 140 may have any suitable shape in accordance with the present disclosure. The reflective film 140 is disposed at or near halfway between the positive and negative electrode leads 160 and 170. However, the reflective film 140 may be disposed at the left side or the right side of the one side surface of the pouch-shaped battery, as needed. For example, the reflective film 140 may be disposed on the left side of the positive electrode lead 160 or the right side of the negative electrode lead 170. It is preferable for the reflective film 140 to be a visible light reflective film or an infrared reflective film. If a battery swells, the temperature of the battery increases in many cases. However, it may not be difficult to definitely determine whether the infrared reflective film is damaged. In such cases, it is preferable to use a visible light reflective film or an ultraviolet reflective film.

In the case in which the electrode leads 160 and 170 are not disposed at one side surface of the pouch-shaped battery 100 but are disposed at different surfaces of the pouch-shaped battery, the reflective film 140 may be disposed at one surface or opposite surfaces of the pouch-shaped battery 100, as needed.

In order to sense swelling of the pouch-shaped battery 100, the reflective film 140 may lack elasticity (or substantially inelastic like paper) or have a predetermined amount of elasticity. In the case in which the pouch-shaped battery 100 swells, the inelastic reflective film can be torn or cut. Additionally or alternative, a reflective film having a predetermined amount of elasticity may be configured to be torn or cut. It is preferable that the reflective film be made of a material that has no or low danger from fire even in the case in which the temperature of a battery cell is high while being capable of being easily damaged (e.g., torn, cut, etc.) by tensile strength (e.g., a predetermined amount of tensile strength), such as film or paper. The surface of the material of the reflective film 140 may be coated with a reflective material so as to be usable as the reflective film.

The surface of the pouch-shaped battery 100 is wrapped by a heat shrinkable film 110. A conductive film 120 (not shown in FIG. 2 for clarity of illustration and explanation)is further added between the heat shrinkable film 110 and a case (or a surface of a case) of the pouch-shaped battery 100. The conductive film 120 has a protrusion 125 formed on one side surface of the pouch-shaped battery, from which the electrode leads 160 and 170 protrude. The protrusion 125, which is configured to conduct heat from the conductive film 120, protrudes outwards from the pouch-shaped battery 100 and is disposed in contact (or coupled) with a cooling portion 210, a description of which will follow, in order to conduct heat from the conductive film 120.

In one embodiment of the present disclosure, the reflective film 140 is separately added. Alternatively, the reflective film may be separately attached to the outermost contour of one side surface of the pouch-shaped battery, or a part of the heat shrinkable film 110 or the conductive film 120 may be further extended so as to be used as the reflective film.

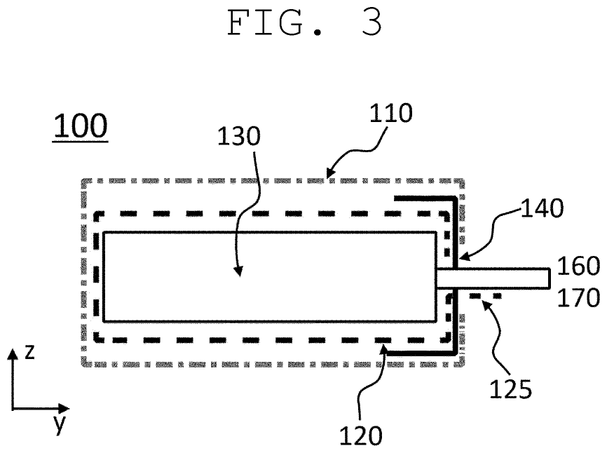

FIG. 3 is a side sectional view of the pouch-shaped battery 100 according to an embodiment of the present disclosure. The outermost contour of the pouch-shaped battery 100 may be wrapped by the heat shrinkable film 110 (indicated by a double chain line). The conductive film 120 (indicated by a dotted line) is further added between the heat shrinkable film 110 and the case of the pouch-shaped battery 100. The conductive film 120 has a protrusion 125 formed on one side surface of the pouch-shaped battery 100, from which the electrode leads 160 and 170 protrude. In FIG. 3, an electrode assembly 130 is shown but a case of the pouch-shaped battery 100 including the electrode assembly 130 is not shown for clarity of description and illustration. All of the heat shrinkable film, the conductive film, and the reflective film according to the present disclosure are disposed outside the case of the pouch-shaped battery.

In FIG. 3, the reflective film 140 is shown as being disposed between the heat shrinkable film 110 and the conductive film 120. Alternatively, the reflective film 140 may be disposed at or near the contour of the heat shrinkable film 110 or in the conductive film 120. However, one side surface of the reflective film 140 must be open (or exposed) outside in order to reflect light irradiated by a light irradiation portion 224 of a swelling sensing unit 220, a description of which will follow.

The reflective film 140 of FIG. 3 is disposed so as to extend to the upper end and the lower end of the pouch-shaped battery 100 over one side surface of the pouch-shaped battery 100, at which the electrode leads 160 and 170 are disposed. The reason for this is that, when the battery swells, a change in length of the one side surface of the pouch-shaped battery 100, at which the electrode leads 160 and 170 are disposed, is not great and expansion of a planar portion of the pouch-shaped battery (a y-axis surface of the pouch-shaped battery 100 in FIG. 3) is greater, and therefore it is more advantageous to sense expansion of the portion. At this time, only the end of the reflective film 140 on the planar portion (the y-axis surface of the pouch-shaped battery in FIG. 3) is fixed to the battery and a partial incision portion 145, a description of which will follow, is not fixed to the pouch-shaped battery 100 such that, when the pouch-shaped battery 100 swells, the partial incision portion 145 is cut (or torn, disconnected, etc.), whereby the swelling sensing unit is capable of easily sensing swelling of the pouch-shaped battery 100.

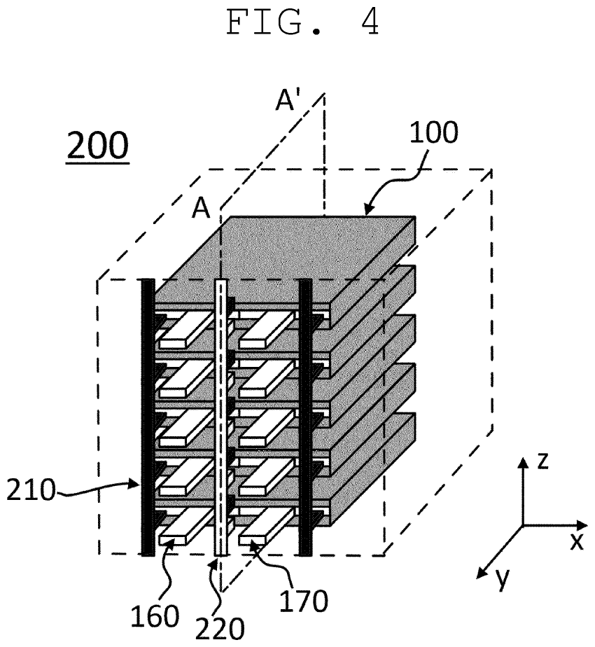

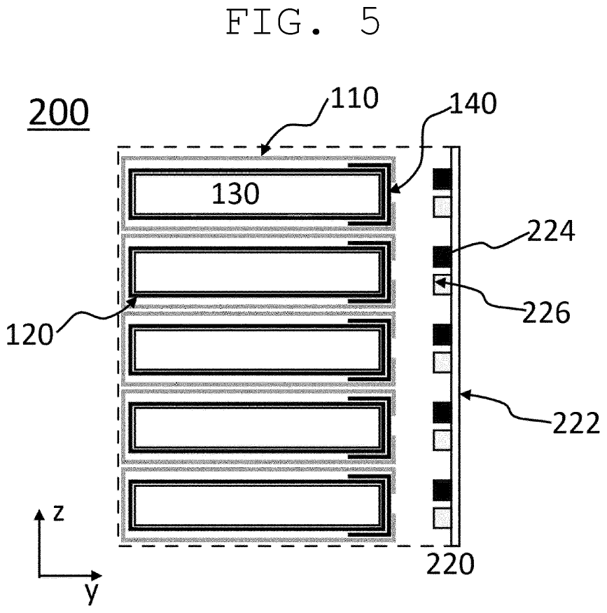

FIG. 4 is a perspective view of a battery pack 200 according to an embodiment of the present disclosure, and FIG. 5 is an AA′ sectional view of the battery pack according to an embodiment of the present disclosure.

The battery pack 200 has at least one pouch-shaped battery 100 disposed therein. The placement or arrangement of the batteries may be changed by those skilled in the art, and therefore a description thereof will be omitted. In FIG. 4, five pouch-shaped batteries 100 are disposed, and protrusions 125 abut a cooling portion 210 configured to lower temperature. The cooling portion 210, which is made of a high thermal conductivity material or is formed so as to have the shape of a pipe having a thermally conductive fluid flowing therein, is connected to a heat dissipation fin or a cooling portion configured to cool the battery pack 200 or is connected to a means configured to dissipate heat through a battery module including a plurality of battery packs coupled to each other or a separate external device.

A swelling sensing unit 220 configured to detect whether reflective films are damaged is provided at or near the middle of a side center portion (an x-z plane) of the battery pack 200. The swelling sensing unit 220 includes a plurality of light irradiation portions 224 and sensors 226 disposed along a sensor support portion 222. Each of the light irradiation portions 224 may be arranged adjacent to each of the plurality of sensors 226.

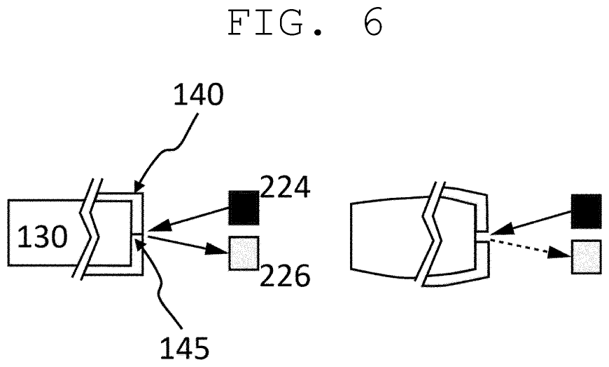

FIG. 6 is a schematic view showing a swelling sensing method according to an embodiment of the present disclosure.

The method of sensing swelling of the pouch-shaped batteries in the battery pack according to the present disclosure includes:

a) a step of the light irradiation portion 224 irradiating the reflective film 140 of a target pouch-shaped battery with light;

b) a step of the sensor 226 sensing light (or amount of light) reflected at one or more regions of the reflective film 140; and

c) a step of determining that the target pouch-shaped battery has swelled in the case in which the sensor 226 does not sense light (or senses a change in the amount of light being sensed) reflected at one or more regions of the reflective film 140.

When the pouch-shaped battery 100 expands due to swelling (see the right part of FIG. 6), whereby the reflective film 140 is torn, and therefore light (or predetermined amount of light) reflected at one or more regions the reflective film 140 is not sensed (or senses a change in the amount of light being sensed), the swelling sensing unit 220 determines that the pouch-shaped battery has swelled. It is preferable that, when the battery swells, a partial incision portion 145 be provided in the reflective film 140 such that a specific region of the reflective film 140 is easily damaged, whereby the specific region is easily cut (or torn, disconnect, etc.).

Although the specific details of the present disclosure have been described in detail, those skilled in the art will appreciate that the detailed description thereof discloses only preferred embodiments of the present disclosure and thus does not limit the scope of the present disclosure. Accordingly, those skilled in the art will appreciate that various changes and modifications are possible, without departing from the category and the technical idea of the present disclosure, and it will be obvious that such changes and modifications fall within the scope of the appended claims.

As is apparent from the above description, the present disclosure has effects in that 1) no large space is occupied, 2) it is possible to easily sense overall swelling of a pouch-battery cell in a battery pack, whereby it is possible to determine whether the battery (cell) is abnormal, and 3) in the case in which pouch-battery cells are stacked in the battery pack, it is possible to efficiently transfer heat generated therein to the outside.

1. A battery comprising:
a case;
an electrode assembly in the case; and
a film on a surface of the battery, the film having a predetermined amount of elasticity or having substantially no elasticity.

2. The battery according to claim 1, wherein the film is a visible light reflective film.

3. The battery according to claim 1, further comprising a heat shrinkable film on the case.

4. The battery according to claim 3, further comprising a heat conductive film between the heat shrinkable film and the case.

5. The battery according to claim 4, wherein the heat conductive film comprises a protrusion formed on the surface.

6. The battery according to claim 4, wherein the heat shrinkable film or the heat conductive film is integrated with the film.

7. A battery pack comprising the battery according to claim 1,
further comprising:
a swelling sensing unit,
the swelling sensing unit comprising a light irradiation portion and a sensor,
wherein the sensor senses light reflected from the film.

8. The battery pack according to claim 7, further comprising a cooling portion coupled to a protrusion formed on the surface.

9. A method of sensing swelling of the battery in the battery pack according to claim 7, the method comprising:
irradiating, by the light irradiation portion, the film of the battery with light;
sensing, by the sensor, the light reflected from the film; and
determining, by the swelling sensing unit, swelling of the battery based on an amount of light sensed by the sensor.

10. The method according to claim 9, further comprising determining that the battery is swelled, when the swelling sensing unit determines the amount of light sensed by the sensor has changed.

11. The battery pack according to claim 7, wherein the battery is in the battery pack, and
wherein the light irradiation portion and the sensor are at a side of the battery pack.

12. The battery according to claim 1, wherein the film is made of paper.

13. The battery according to claim 1, wherein the film is cut or torn when a predetermined amount of tensile strength is applied to the film.

14. The battery according to claim 5, wherein the protrusion conducts heat from the heat conductive film.

15. The battery according to claim 6, wherein a part of the heat shrinkable film or a part of the heat conductive film is the film.

16. The battery according to claim 1, wherein the film comprises a partial incision portion.

17. A battery pack comprising:
a plurality of batteries, each of the plurality of batteries comprising a film on a surface of each of the plurality of batteries; and
a swelling sensing unit, the swelling sensing unit comprising a light irradiation portion and a sensor,
wherein at least one of the plurality of batteries is a target battery.

18. The battery pack according to claim 17, wherein the light irradiation portion irradiates light on the film of the target battery;
wherein the sensor senses light reflected from the film of the target battery; and
wherein the swelling sensing unit determines swelling of the battery based on an amount of light sensed by the sensor.

19. A method of sensing swelling of a target battery of a battery pack, the battery pack comprising:
a plurality of batteries, each of the plurality of batteries comprising a film on a surface of each of the plurality of batteries; and
a swelling sensing unit, the swelling sensing unit comprising a light irradiation portion and a sensor,
wherein at least one of the plurality of batteries is a target battery,
wherein the method comprises:
irradiating, by the light irradiation portion, a film of the target battery with light;
sensing, by the sensor, the light reflected from the film; and
determining, by the swelling sensing unit, swelling of the battery based on an amount of light sensed by the sensor.

20. The method of claim 19, wherein the film comprises a partial incision portion,
wherein the light irradiation portion irradiates the partial incision portion with the light.
